(19) United States
(12) Patent Application Publication
(10) Pub. No.: US 2025/0283246 A1
(43) Pub. Date: Sep. 11, 2025

(54) PRODUCTION METHOD FOR A BULK SIC SINGLE CRYSTAL

(71) Applicant: SiCrystal GmbH, Nürnberg (DE)

(72) Inventors: Philipp SCHUH, Nürnberg (DE); Ralf MÜLLER, Nürnberg (DE); Matthias STOCKMEIER, Nürnberg (DE); Michael VOGEL, Nürnberg (DE); Bernhard ECKER, Nürnberg (DE); Wenzel KLIETZ, Nürnberg (DE)

(21) Appl. No.: 19/075,926

(22) Filed: Mar. 11, 2025

(30) Foreign Application Priority Data
Mar. 11, 2024 (EP) 24162681.1

(51) Int. Cl. C30B 23/00; C30B 29/36

(52) U.S. Cl. CPC C30B 23/002; C30B 29/36

(57) ABSTRACT

A bulk SiC single crystal is produced by sublimation growth. A stress measurement to detect initial internal mechanical seed stresses is carried out on a wafer-shaped single crystalline SiC seed crystal. The seed crystal is classified, according to the stress measurement, into a first class when the initial seed stresses are below a first stress boundary value, into a second class when the initial seed stresses lie between the first stress boundary value and a second stress boundary value, and into a third class when the initial seed stresses exceed the second stress boundary value. The actual sublimation growth for growing the bulk SiC single crystal is carried out with the SiC seed crystal only when it has been classified into the first or second class, and when it is classified into the second class, at least one stress-reducing measure is carried out.

### CROSS-REFERENCE TO RELATED APPLICATION

This application claims the priority, under 35 U.S.C. § 119, of European Patent Application EP 24 162 681.1, filed Mar. 11, 2024; the prior application is herewith incorporated by reference in its entirety.

### FIELD AND BACKGROUND OF THE INVENTION

The invention relates to a method for the production of at least one bulk SiC single crystal by means of sublimation growth.

By reason of its excellent physical, chemical, electrical and optical properties, the semi-conductor material silicon carbide (SiC) is also used, inter alia, as a starting material for power-switching semi-conductor components, for high-frequency components and for special light-emitting semi-conductor components. These components require SiC substrates (=SiC wafers) with the largest possible substrate diameter and of the highest possible quality. These are based on high-value bulk SiC single crystals.

Such bulk SiC single crystals are generally produced by means of physical vapor transport (PVT), e.g. by means of a sublimation method described in U.S. Pat. No. 8,865,324 B2. In that case, a single crystalline SiC wafer as an SiC seed crystal is introduced into a growth crucible together with a suitable source material. Under controlled temperature, pressure and gas conditions, the source material is sublimated. The gaseous species (=SiC, Si2C, SiC2) are transported to the SiC seed crystal by reason of an axial temperature gradient and there are deposited on the SiC seed crystal from the SiC growth gas phase, whereby the bulk SiC single crystal grows.

From these bulk SiC single crystals the wafer-like single crystalline SiC substrates are cut, e.g. by means of a wire saw, which are then, after an—in particular—multi-stage polishing treatment of their surface as part of component manufacture, provided with at least one epitaxial layer also consisting in particular of SiC. Defects are generally passed on from the SiC substrate into the applied epitaxial layer and therefore lead to an impairment of the component properties. The quality of the components thus essentially depends on that of the grown bulk SiC single crystal and the SiC substrate obtained therefrom.

The geometry of the SiC substrate used is of great significance for the production of the epitaxial layers of the components. Thus, in an epitaxial reactor good thermal coupling, which is very important for homogeneous and high-quality epitaxial layer growth, is essentially achieved only in the case of SiC substrates which have no appreciable bowing. In contrast, SiC substrates with poor geometric properties, i.e. in particular with an excessive amount of bow and/or warp, inevitably lead to poorer quality and/or lower yield from the epitaxial process.

A further aspect which can reduce the quality of the SiC substrate are stresses in the material. Stresses present in the grown bulk SiC single crystal can lead specifically to the formation of crystal defects (e.g. especially dislocations), to breaks during further processing or to deformations (see above) in the SiC substrates produced from such a bulk SiC single crystal. The economic production capability of the SiC substrates is thereby massively impaired. Furthermore, SiC substrates with such stress-induced deformations can only go on to limited further use.

European published patent application EP 3 048 641 A1 describes the measurement of these stresses in SiC substrates in order to estimate the bowing which the SiC substrates will display during further processing. Measurement methods suitable for this purpose are based on the detection and evaluation of Raman scattering or Raman shift on the SiC crystal lattice or of X-ray diffraction on the SiC crystal lattice.

The undesired stresses can arise during SiC crystal growth during the growing process by reason of the temperature gradients required for the crystal growth. These thermal effects are produced in that, on the one hand, a moving force for the material transport is required (=temperature difference from the SiC source material to the SiC seed crystal), and, on the other hand, the growth boundary (=growth surface) of the growing bulk SiC single crystal must have a certain convex curvature in order to prevent the propagation of defects from the radial edge region in the direction of the center of the crystal. However, the stresses in the bulk SiC single crystal can also be caused by forces which form between a crucible wall and the grown bulk SiC single crystal, e.g. during the cooling after termination of the actual growth process by reason of a different cooling behavior in the growth crucible and the bulk SiC single crystal. Thus in this case, wall effects are the cause. The wall effects and thermal effects responsible for stresses in the material are triggered or determined by processing parameters during the SiC growth. Suitable construction of the growth apparatus and/or suitable process guidance can, at least to a certain extent, counteract the thermal effects and the wall effects as causes of stress.

Chinese document CN 218860954 U describes the temperature within the SiC seed crystal being rendered uniform. Temperature differences and therefore internal stresses in the SiC seed crystal resulting from the thermal effects should thus be reduced. For this purpose, a multi-part thermal insulation which contains a displaceable adaptation element, is disposed on the rear side of the SiC seed crystal. Displacement of said adaptation element means that a cavity also provided on the rear side of the SiC seed crystal can be adapted in its dimensions to the respective (thermal) conditions. However, this construction is complex and therefore also expensive.

Chinese document CN 116334748 A describes how, in order to avoid stresses caused by wall effects, a two-layer insert with porous graphite in the inner layer and with hard graphite in the outer layer is introduced between the inner wall of the growth crucible and the SiC seed crystal and the bulk SiC single crystal growing thereon.

Furthermore, in most SiC growth processes, the SiC seed crystal is suitably fixedly connected to the structure used for the growth. Such a firm adhesive connection of the SiC seed crystal to the crucible cover, then also serving as a seed holder, is described, for example, in published patent application No. US 2011/0229719 A1. In addition, another embodiment is disclosed in which the SiC seed crystal is fastened by means of a lateral mechanical holder on the crucible cover. The SiC seed crystal lies only loosely on the lateral holder and the crucible cover. Chinese document CN 110306239 A describes the use of a crucible cover made of polycrystalline SiC. The SiC seed crystal is attached by means of a firm adhesive connection to this crucible cover also serving again as a seed holder.

### SUMMARY OF THE INVENTION

The object of the invention is that of providing a method of the type described in the introductory part which, in comparison to the known methods, makes it possible to produce a bulk SiC single crystal with fewer stresses.

With the above and other objects in view there is provided, in accordance with the invention, a method for producing bulk silicon carbide (SiC) single crystal by sublimation growth, the method comprising:
a) carrying out a stress measurement to detect initial internal mechanical seed stresses on a wafer-shaped single crystalline SiC seed crystal, the SiC seed crystal having a wafer front side with a growth surface intended for a growth of the bulk SiC single crystal to be grown, a wafer rear side and a crystal longitudinal mid-axis extending in an axial direction, and wherein a radial direction is orientated perpendicularly to the axial direction;
b) carrying out a classification of the SiC seed crystal with the aid of the stress measurement, to thereby classify the SiC seed crystal:
   b1) into a first class when the detected initial seed stresses are below a first stress boundary value;
   b2) into a second class when the detected initial seed stresses lie between the first stress boundary value and a second stress boundary value; or
   b3) into a third class when the detected initial seed stresses exceed the second stress boundary value;
and
c) carrying out the sublimation growth, during which the bulk SiC single crystal grows on the SiC seed crystal, with the SiC seed crystal only when the SiC seed crystal has been classified into the first class or into the second class;
   c1) when the SiC seed crystal has been classified into the second class, carrying out at least one stress-reducing measure.

In other words, in the method according to the invention a stress measurement to detect initial internal mechanical seed stresses is carried out on a wafer-like single crystalline SiC seed crystal, wherein the SiC seed crystal has a wafer front side with a growth surface intended for the growth of the bulk SiC single crystal to be grown, a wafer rear side opposite in particular the wafer front side, and a crystal longitudinal mid-axis extending in an axial direction, and wherein a radial direction is orientated perpendicularly to the axial direction. Furthermore, with the aid of the stress measurement a classification of the SiC seed crystal is carried out, wherein the SiC seed crystal is classified into a first class when the detected initial seed stresses are below a first stress boundary value, is classified into a second class when the detected initial seed stresses lie between the first stress boundary value and a second stress boundary value, or is classified into a third class when the detected initial seed stresses exceed the second stress boundary value. Furthermore, the actual sublimation growth, during which the bulk SiC single crystal grows on the SiC seed crystal is carried out with the SiC seed crystal only when it has been classified into the first or into the second class, wherein in the case of classification into the second class, at least one stress-reducing measure is carried out.

The term “sublimation growth” is to be understood generally herein. In particular, it also comprises steps for pre- and/or post-processing the actual growth process which is also referred to herein as actual sublimation growth.

The stress measurement for the detection of initial inner mechanical seed stresses can take place on the wafer-like single crystalline SiC seed crystal, in particular in its non-constructed or non-mounted state or in particular also in a fixedly mounted state as a component of a seed unit. Moreover, this seed unit can comprise in particular a seed holder and a connection medium, such as e.g. an adhesive layer, between the SiC seed crystal and the seed holder. The seed unit can also be referred to as a seed system. During measurement on a non-mounted SiC seed crystal the measured initial seed stresses are the stresses which have arisen in the micro-structures of the SiC seed crystal during production thereof. During measurement on an SiC seed crystal fixedly mounted in a seed unit, the measured initial seed stresses are composed of two stress components, specifically, on the one hand, once again of the stresses which have arisen in the crystal micro-structure of the SiC seed crystal during production thereof, as a first stress component, but, on the other hand, also of a second stress component which comes about by reason of the different expansion coefficients of the SiC seed crystal and the other components of the seed unit, e.g. of the seed holder and of the connection medium.

The at least one stress-reducing measure to be carried out in the case of classification into the second class is in particular an additional measure which otherwise would not normally be resorted to e.g. in the case of classification into the first class.

The wafer-like SiC seed crystal has, in particular, a substantially cylindrical geometry. A peripheral edge surface of the SiC seed crystal has, in particular, essentially the shape of a cylindrical outer surface.

During growth the bulk SiC single crystal grows in the axial direction on the SiC seed crystal and has the same crystal longitudinal mid-axis as the SiC seed crystal or the seed unit. In this case “axial” is to be understood to mean a direction parallel to, or along, the in particular central crystal longitudinal mid-axis, “radial” is to be understood to mean a direction perpendicular thereto and “tangential” is to be understood to mean a peripheral direction around the crystal longitudinal mid-axis.

It has been recognized that undesired stresses within the bulk SiC single crystal can also be caused by initial seed stresses which are present even before growth starts within the SiC seed crystal or within the seed unit (=seed system) formed therewith and are transmitted from the SiC seed crystal or from the seed unit to the bulk SiC single crystal growing thereon. Seed effects are thus the cause in this case.

Stresses in the growing bulk SiC single crystal, which are based on such seed effects, are more difficult to influence that other stresses. Furthermore, initial seed stresses from the SiC seed crystal or the seed unit during the growth process has a much greater influence on the growing bulk SiC single crystal than as is known from other growth processes which are used for the production of other technologically significant crystals. In the case of SiC growth, an SiC seed crystal is normally used which has a comparable diameter to the bulk SiC single crystal growing thereon. During the SiC growth, only a small increase in diameter, if any, can be achieved, which distinguishes the SiC growth from thin-neck crystal growth methods as used e.g. in the growth of pure silicon (Si) crystals.

In order to be able to counteract the influence of the initial seed stresses from the SiC seed crystal or the seed unit on the stress balance in the growing bulk SiC single crystal, these initial seed stresses must be known, for which reason they are measured in the method in accordance with the invention.

The knowledge from this stress measurement carried out in particular individually for each SiC seed crystal is then used firstly for the decision as to whether the examined SiC seed crystal is even suitable for the growth of a bulk SiC single crystal (=first and second class), and if so, whether for this purpose a stress-reducing measure is to be carried out (=second class) or not (=first class). If the examined SiC seed crystal falls into the second class by reason of its stress balance and consequently a stress-reducing measure is required, the growth process is adapted to the stress conditions present in the SiC seed crystal in order thus to react to the initial seed stresses during growth. In this way, the initial seed stresses are counteracted and a very low-stress bulk SiC single crystal can be grown. On low-stress SiC seed crystals falling into the first class it is possible to grow such very low-stress bulk SiC single crystals even without stress-reducing measures.

With the method in accordance with the invention it is possible for the first time individually to determine the initial seed stresses in each SiC seed crystal and, in the event that a requirement is detected, to react thereto with suitable customised stress-reducing measures during SiC crystal growth. In this way, the bulk single crystal stresses in the growing bulk SiC single crystals can be reduced significantly, which also leads to a clear improvement in the quality of the SiC substrates which are obtained from the bulk SiC single crystals thus produced. The substrate quality is improved directly through the greatly reduced propagation of stresses out of the SiC seed crystal.

Advantageous embodiments of the method according to the invention are outlined in the dependent claims.

An embodiment is favorable in which, with the aid of stress measurement, an in particular complete and/or in particular relative stress distribution of the initial seed stresses in the SiC seed crystal is determined. In this way, very precise knowledge relating to the stress conditions in the SiC seed crystal is provided and so the decisions on the further use of the examined SiC seed crystal can be made in a well founded way.

According to a further favorable embodiment, a stress difference which is measured between a center of the SiC seed crystal disposed on the crystal longitudinal mid-axis and a radial edge region of the SiC seed crystal and which is in the range between 5 MPa and 15 MPa, in particular in the range between 7.5 MPa and 12.5 MPa, and preferably at 10 MPa, is used as a first stress boundary value. According to a further favorable embodiment, a stress difference which is measured between a center of the SiC seed crystal disposed on the crystal longitudinal mid-axis and a radial edge region of the SiC seed crystal and which is in the range between 400 MPa and 600 MPa, in particular in the range between 450 MPa and 550 MPa, and preferably at 500 MPa, is used as a second stress boundary value. In particular, in order to determine the stress difference, a first differential stress measurement in the center of the SiC seed crystal and a second differential stress measurement in the radial edge region is carried out. In particular, the second differential stress measurement is carried out in the radial edge region at an edge measuring point which in the radial direction is spaced by an edge distance from a side wall laterally delimiting the SiC seed crystal or from a side edge of the SiC seed crystal, wherein the edge distance has a value between 0.5 mm and 6 mm, preferably a value between 1 mm and 5 mm and preferably a value of 1 mm or of 3 mm or of 5 mm.

According to a further favorable embodiment, the stress measurement on the SiC seed crystal is carried out by means of X-ray diffraction measurement, neutron diffraction measurement, measurement of the Raman shift or a measurement of the photoelasticity. In particular, any combination of these measurement methods is possible. By means of these measurement methods, the initial seed stresses in the material micro-structure of the SiC seed crystal can be determined in a non-destructive, non-contaminating, space-resolved and highly precise manner. Comparable results are not possible with other methods, such as e.g. computer simulations of the growth apparatuses used. At best, these other methods may produce unsatisfactory rough estimations of the stress conditions in the SiC seed crystal.

According to a further favorable embodiment, the at least one stress-reducing measure consists of bringing the wafer rear side of the SiC seed crystal into contact with stress-reducing elements, wherein the stress-reducing elements have different levels of heat conductivity. In particular, the stress-reducing elements contact the SiC seed crystal directly, which preferably takes place in the case of an SiC seed crystal freely accessible on the wafer rear side. Alternatively, however the wafer rear side of the SiC seed crystal can also only be brought into in indirect contact with the stress-reducing elements, which preferably takes place when another component already lies directly on the wafer rear side of the SiC seed crystal, as may be the case e.g. in the event that the SiC seed crystal is bound or mounted into a seed unit.

According to a further favorable embodiment, the at least one stress-reducing measure consists of the use of an apparatus for the sublimation growth, which comprises at least one transverse cavity in a region axially adjoining the wafer rear side of the SiC seed crystal introduced into the apparatus. The transverse cavity is preferably disposed directly adjacent to the wafer rear side of the SiC seed crystal. It is then possible to influence the seed stresses in a particular effective and efficient manner. The transverse cavity is preferably disposed in an axial front end wall of a growth crucible used for the sublimation growth as a component of the apparatus. This results in a very compact but still effective construction, the outer and inner contours and dimensions of which do not practically differ from those of an SiC growth apparatus without a stress-reducing measure.

According to a further favorable embodiment, the at least one stress-reducing measure consists of an apparatus with a growth crucible being used for the sublimation growth, wherein an axial front end wall of the growth crucible disposed adjacent to the SiC seed crystal introduced into the apparatus has at least one, in particular, external recess. A very compact and effective structure is also thereby produced.

According to a further favorable embodiment, the at least one stress-reducing measure consists of an apparatus with a growth crucible being used for the sublimation growth, wherein an side wall of the growth crucible surrounding the SiC seed crystal and a crystal growth area, in particular tangentially or concentrically to the crystal longitudinal mid-axis, has at least one longitudinal cavity. Once again this results in a very compact effective construction, the outer and inner contours and dimensions of which do not practically differ from those of an SiC growth apparatus without a stress-reducing measure.

According to a further favorable embodiment, the at least one stress-reducing measure consists of coating the wafer rear side of the SiC seed crystal with an, in particular, single-layer or multi-layer rear-side layer component. The rear-side layer component can, in particular, only have a single layer or preferably also be composed of a plurality of individual layers or single layers which can be disposed radially next to each other and/or axially over one another. In particular, the rear-side layer component covers the SiC seed crystal completely. Preferably, for the rear-side layer component, at least two mutually different layer materials with, in particular, different levels of heat conductivity are provided. In this way a particularly good stress-reducing effect and a very good level of compensation for the seed stresses initially contained in the SiC seed crystal can be achieved.

According to a further favorable embodiment, any combination of the above-described favorable stress-reducing measures can be used.

According to a further favorable embodiment, in particular after conclusion of the actual sublimation growth, an, in particular, complete stress distribution of the internal mechanical bulk single crystal stresses in the produced bulk SiC single crystal can be determined. The determining of a complete stress distribution is also referred to in particular as stress mapping. Preferably, with the aid of the determined stress distribution, the further use of the bulk SiC single crystal can be determined. Preferably, the stress distribution of the bulk single crystal stresses is determined by means of X-ray diffraction measurement, neutron diffraction measurement, measurement of the Raman shift or a measurement of the photoelasticity. In particular, any combination of these measurement methods is possible.

Although the invention is illustrated and described herein as embodied in a production method for a bulk SiC single crystal, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 shows a schematic view of an exemplified embodiment of a measuring arrangement for detecting seed stresses in a wafer-shaped SiC seed crystal;

FIG. 2 shows a plan view of a wafer front side of the SiC seed crystal examined using measuring technology according to FIG. 1;

FIG. 3 shows a stress distribution determined for the examined SiC seed crystal according to FIGS. 1 and 2, and a plan view of stress-reducing elements for contact with the wafer rear side of the SiC seed crystal according to FIGS. 1 and 2; and

FIGS. 4 to 9 show exemplary embodiments of growth apparatuses for the growth of a bulk SiC single crystal on an SiC seed crystal examined using measuring technology according to FIG. 1.

Mutually corresponding parts are provided with the same reference signs throughout the figures.

Details of the exemplary embodiments explained in more detail hereinunder may also constitute the invention in their own right or be part of inventive subject matter.

### DETAILED DESCRIPTION OF THE INVENTION

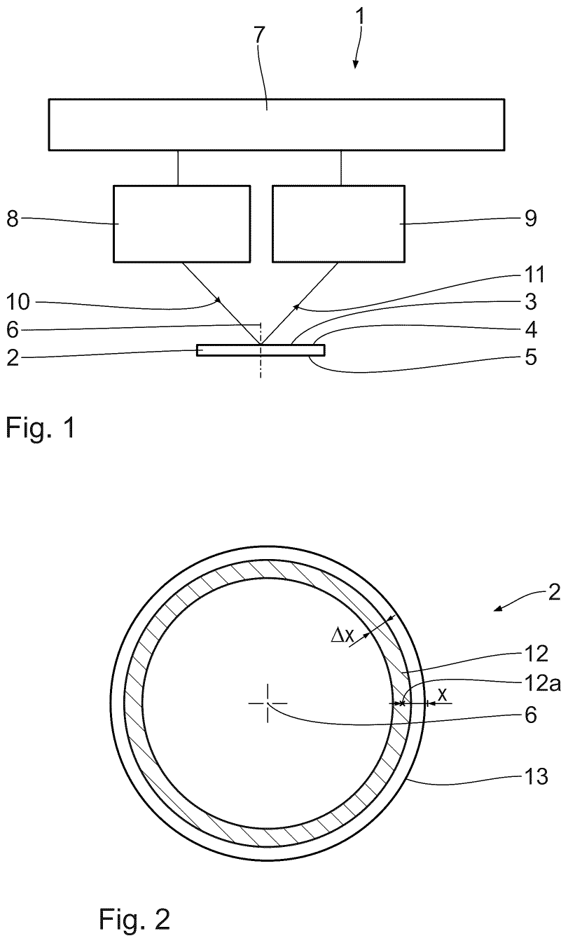

Referring now to the figures of the drawing in detail and first, in particular, to FIG. 1 thereof, there is shown a highly schematic illustration of an exemplary embodiment of a measuring arrangement 1 for examining a single crystalline wafer-like SiC seed crystal 2.

The SiC seed crystal 2 intended for the growth of a bulk SiC single crystal is illustrated in FIG. 1 in a side view and in FIG. 2 in a plan view. The SiC seed crystal 2 has a growth surface 3 for the growth of the bulk SiC single crystal to be grown, which surface is disposed on a wafer front side 4 of the SiC seed crystal 2. Furthermore, the SiC seed crystal 2 has a wafer rear side 5 opposite the wafer front side 4.

Furthermore, the SiC seed crystal 2 has a central crystal longitudinal mid-axis 6. It coincides with the middle axis of symmetry of the, in particular, cylindrical geometry of the SiC seed crystal 2. A direction along the crystal longitudinal mid-axis 6 or parallel thereto is referred to as axial herein. A direction perpendicular to the crystal longitudinal mid-axis 6 is referred to as radial. A peripheral direction extending around the crystal longitudinal mid-axis 6 is tangential.

The measuring arrangement 1 illustrated in FIG. 1 is intended to detect seed stresses which are present in the crystal micro-structure of the SiC seed crystal 2 initially, i.e. even before the beginning of the actual SiC growth process. In the case of the exemplified embodiment shown in FIG. 1, the examined SiC seed crystal 2 is non-mounted. In an alternative exemplified embodiment, the SiC seed crystal 2 can be in the mounted condition during the examination using measuring technology, e.g. as a component of a seed unit. It is then, in particular, fixedly connected to other components of the seed unit in question. The seed stresses detected in the case of such a mounted SiC seed crystal 2 are composed of two stress components. The first stress component pertains to the already mentioned stresses which are present in the crystal micro-structure of the SiC seed crystal 2 by reason of its production. The second stress component is caused by the different thermal expansion coefficients of the different mounted single components of the seed unit in question.

The measuring arrangement 1 comprises a control/evaluation unit 7, a transmitting unit 8, or transmitter 8, and a receiving unit 9, or receiver 9. After an appropriate actuation by the control/evaluation unit 7 the transmitting unit 8 directs an interrogation signal 10 to the SiC seed crystal 2 where an interaction with the stressed crystal micro-structure thereof takes place. The interrogation signal 10 is influenced by means of this interaction so that it contains information about the seed stresses present in the SiC seed crystal 2. It then reaches the receiving unit 9 as a reply signal 11, where it is detected. The evaluation is then effected by the control/evaluation unit 7 which is connected both to the transmitting unit 8 and also to the receiving unit 9.

Furthermore, the measuring arrangement 1 is designed to determine a complete stress distribution of the seed stresses in the SiC seed crystal 2. For this purpose, the interrogation signal 10 is directed to different points of the growth surface 3 on the wafer front side 4 of the SiC seed crystal 2. In the case of an alternative examination method, the interrogation signal 10 is also basically directed at the wafer rear side 5 onto the SiC seed crystal 2. After termination of the examination sensing the growth surface 3 there is a complete image of the stress distribution in the SiC seed crystal 2 in the control/evaluation unit 7. A decision is made with the aid thereof as to how the SiC seed crystal 2 can go on to be used. For this purpose a classification is carried out with the aid of two stress boundary values σG1 and σG2. The SiC seed crystal 2 is classified into a first class when the detected seed stresses are below the first stress boundary value σG1. A classification into the second class is effected when the seed stresses lie between the first stress boundary value σG1 and the second stress boundary value σG2. The SiC seed crystal 2 is assigned to the third class when the detected seed stresses exceed the second stress boundary value σG2.

The two stress boundary values σG1 and σG2 are each formed as a difference of two detected stress values. The first stress value is determined in the center of the crystal longitudinal mid-axis 6 of the SiC seed crystal 2, the second stress value in a radial edge region 12 (marked by hatching in FIG. 2). The radial edge region 12 does not abut directly against a lateral peripheral edge 13 of the SiC seed crystal 2, but rather begins only at a distance radially further away from this lateral peripheral edge 13. The second stress value is detected at an edge measuring point 12a within the radial edge region 12. The radial edge distance x thereof from the lateral peripheral edge 13 is, in particular, in a range between 1 mm and 5 mm. The radial expansion Δx of the radial edge region 12 is therefore 4 mm. In the illustrated exemplified embodiment, the second stress value required for the stress difference is detected at an edge distance x of about 3 mm. In the exemplified embodiment, the stress boundary values thus defined for the classification of the SiC seed crystal are 10 MPa for the first stress boundary value σG1 and 500 MPa for the second stress boundary value σG2. For the comparison of the detected seed stresses with these two stress boundary values σG1 and σG21 which is to be carried out for the classification, a difference is formed between the seed stress determined in the center of the examined SiC seed crystal 2 at the location of the crystal longitudinal mid-axis 6 and a second seed stress detected in the radial edge region 12, in the case of the illustrated exemplified embodiment at an edge distance x of 3 mm away from the lateral peripheral edge 13 at the edge measuring point 12a, and is compared with the two stress boundary values σG1 and σG2.

The further use of the thus examined SiC seed crystal 2 is directed by the classification. In the case of classification into the first class, the examined SiC seed crystal 2 has only very low initial seed stresses. It can be used without any additional measures to grow a low-stress bulk SiC single crystal. In the case of classification into the second class, the SiC seed crystal 2 has greater initial seed stresses but these still allow use of the SiC seed crystal 2 for the growth of a bulk SiC single crystal if additional stress-reducing measures are taken which counteract the initial seed stresses during SiC crystal growth and in this respect allow the growth of a low-stress bulk SiC single crystal. In the case of classification into the third class, the SiC seed crystal 2 has too many initial seed stresses and so it cannot be used to grow bulk SiC single crystal. Instead, it is rejected.

The measuring principle on which the measuring arrangement 1 is based can vary. The stress measurement on the SiC seed crystal 2 can be effected, in particular, by means of a measurement of the Raman shift, a measurement of the photoelasticity, an X-ray diffraction measurement and/or a neutron diffraction measurement.

The stress measurement by means of measuring the Raman shift is explained hereinunder.

By reason of the strong covalent Si—C bonds, the effects caused by stresses on the Raman shift are very small, for which reason absolute measurement of the stresses is difficult. Therefore, a relative measurement is used, in which by means of a dot matrix covering the whole growth surface 3 of the examined SiC seed crystal 2, the Raman shift values are determined in relation to a reference point (generally the center of the growth surface 3). The stress can also be deduced from the following equation:

$$Δ ω = ψ \cdot σ$$

where ψ designates the stress-extension-frequency shift factor of the material, Δω designates the frequency shift increment and σ designates the stress.

Stress measurement using measurement of the photoelasticity is explained hereinunder.

By the influence of stresses on the arrangement of the atoms in the crystal structure of the material, the optical properties are also influenced. A beam of light which penetrates through the material is split into two rays with different propagation velocities; in this way in the case of polarized light a phase lag arises, whereby it is possible to draw a conclusion as to the stresses in the material. The following equation is applicable:

$$Δ = \frac{2 π t}{λ} C ( {σ}_{1} - {σ}_{2} )$$

where Δdesignates the phase lag, C designates the stress-optical coefficients, t designates the thickness of the sample, λ designates the vacuum optical wavelength, σ1 and σ2 designate the first and second main stress respectively.

Stress measurement using X-ray diffraction measurement and neutron diffraction measurement is explained hereinunder.

The influence of the stresses on the arrangement of the atoms in the crystal structure also influences the results of diffraction experiments and can be tailored thereto. By reason of the stresses the lattice plane spacings of the crystal structure are changed, which can be measured by X-ray or neutron diffraction experiments. It is possible to made a decision as to the stresses and the stress direction in the material. The following equations are applicable to this:

$${ε}_{hkl} = ( dhkl - dhkl , 0 ) \cdot dhkl , 0$$

$$σ hkl = E \cdot ε hkl$$

where εₙₖₗ designates the distortion of the observed diffraction plane, dₙₖₗ designates the real lattice plane spacing, d_{nkl,0} designates the ideal undistorted lattice plane spacing, E designates the modulus of elasticity and σₙₖₗ designates the stress.

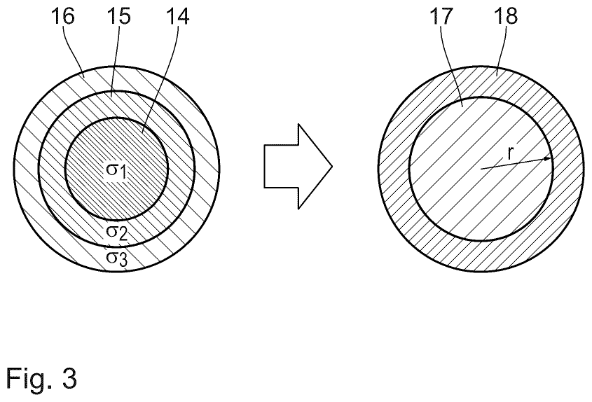

After determining a complete stress distribution (=stress mapping) within the examined SiC seed crystal 2, e.g. with one of the above-described methods, the wafer-like SiC seed crystal 2 can be divided into suitable zones with different stress value ranges which, by reason of the conditions prevailing in the SiC crystal growth, are generally radially symmetrical (see left-hand image in FIG. 3).

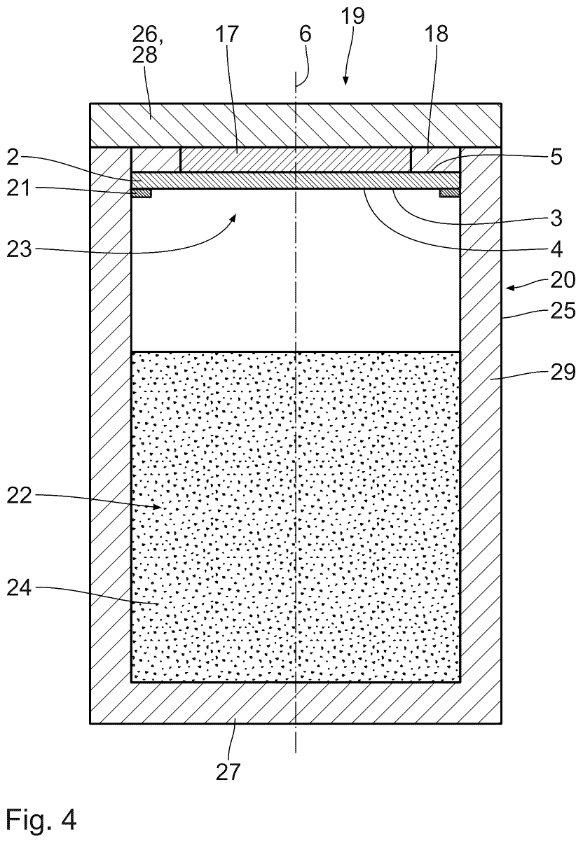

As already mentioned, an SiC seed crystal 2 classified into the second class is used for the growth of a bulk SiC single crystal, wherein, however, additional measures (see FIG. 3, right-hand image, and FIGS. 4 to 9) are taken in order to reduce the stresses during the actual SiC growth process.

FIG. 3 shows, in the left-hand image, a stress zone diagram of an examined SiC seed crystal 2 derived from the determined stress distribution, the seed crystal having been classified into the second class. According to the stress zone diagram, this SiC seed crystal 2 comprises an inner central region 14 with little distortion and with initial seed stresses σ1, a transfer region 15 with somewhat greater initial seed stresses σ2 and a highly distorted edge region 16 with relatively high initial seed stresses σ3. The three regions 14, 15 and 16 are each disposed radially symmetrically and concentrically with respect to each other. The seed stresses σ1, σ2, σ3 can also be stress differential values, in which in each case the value determined in the center is used as a reference value for the subtraction.

The stress distribution of an examined SiC seed crystal 2 with more strongly distorted edge region 16, shown schematically in the left-hand image of FIG. 3, is mainly to be attributed to the convexly curved isotherms used during the production of the SiC seed crystal 2 in question. In order to counteract the initial seed stresses σ1, σ2, σ3 during the SiC sublimation growth of a bulk SiC single crystal growing on this SiC seed crystal 2 the heat discharge out of the SiC seed crystal 2 in the strongly distorted edge region 16 is increased with respect to the central region 14 with little distortion. In this way, the curvature of the isotherms is reduced locally during the SiC sublimation growth of the bulk SiC single crystal. This is effected e.g. by the use of stress-reducing elements 17 and 18, shown in the right-hand image of FIG. 3, which have a different level of heat conductivity and which are brought into direct contact with the SiC seed crystal 2 on the wafer rear side 5. The two stress-reducing elements 17 and 18 are each designed radially symmetrically and disposed concentrically with respect to each other. The radius r, which determines the boundary between the central stress-reducing element 17 and the outer annular stress-reducing element 18 tangential thereto, is selected by reason of the determined complete distribution of the initial seed stresses within the SiC seed crystal 2. In this way, the growth conditions during the SiC sublimation growth of the bulk SiC single crystal are individually adapted to the stress conditions prevailing in the SiC seed crystal 2 used for this purpose. In the illustrated exemplified embodiment, the inner stress-reducing element 17 has a lower level of heat conductivity than the outer stress-reducing element 18. By reason of the additionally provided stress-reducing measures, the bulk SiC single crystal grown in this way has only very low internal stresses. In this respect, very high-quality SiC substrates and similarly high-quality SiC components can be produced therefrom with a high yield.

FIG. 4 shows an exemplified embodiment of a growth apparatus 19 for the production of a bulk SiC single crystal (not also shown) by means of sublimation growth and using the SiC seed crystal 2 examined using measuring technology according to FIG. 1.

The stress-reducing elements 17 and 18 according to FIG. 3 are used in the growth apparatus 19. They are placed loose on the wafer rear side 5 of the SiC seed crystal 2 which is held in a growth crucible 20 by means of a seed holder 21.

The growth crucible 20 comprises an SiC storage area 22 and a crystal growth area 23. The SiC storage area 22 contains e.g. powdered SiC source material 24.

The growth crucible 20 has a crucible vessel 25 and a crucible cover 26. The growth crucible 20 has a first axial front end wall 27, which is disposed adjacent to the SiC storage area 22, and a second axial front end wall 28 opposite thereto, which is formed by the crucible cover 26. Furthermore, the growth crucible 20 has a tangentially peripheral side wall 29 which, like the first axial front end wall 27, is a component of the crucible vessel 25. The SiC seed crystal 2 is positioned in the growth crucible 20 by means of the seed holder 21 in such a way that the wafer front side 4 of the SiC seed crystal 2 is disposed with the growth surface 3 in the crystal growth area 23. In the illustrated exemplified embodiment, the wafer front side 4 of the SiC seed crystal 2 in the region of the peripheral edge lies loose on the annular seed holder 21.

The growth crucible 20 consists of an electrically and thermally conductive graphite crucible material. A thermal insulation, not shown in FIG. 4, is disposed around it. Furthermore, in order to heat the growth crucible 20 an, in particular, inductive heating device in the form of a heating coil is provided, also not shown. The growth crucible 20 is heated by means of this heating device to the high temperatures of over 2100° C. required for the growth.

The SiC growth gas phase in the crystal growth area 23 is fed through the SiC source material 24. The SiC growth gas phase contains at least gas components in the form of SiC, Si2C and SiC2 (=SiC gas species). The material transport from the SiC source material 24 to the growth surface 3 takes place along an axial temperature gradient which is set by means of the heating device and extends parallel to the crystal longitudinal mid-axis 6. A relatively high growth temperature of at least 2100° C., in particular of even at least 2200° C. or 2300° C. prevails at the growth surface 3. At that location gas components of the SiC growth gas phase are deposited, which leads to the growth of the bulk SiC single crystal. The temperature falls within the growth crucible 20 from the SiC source material 24 in the axial direction to the crucible cover 26, whereby the axial temperature gradient mentioned above is created.

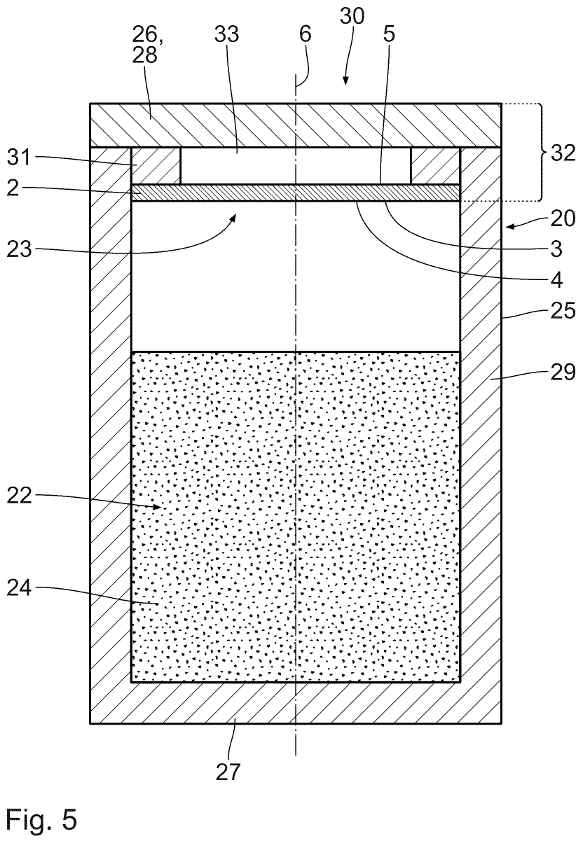

FIG. 5 shows a further exemplified embodiment of a growth apparatus 30 for the growth of a bulk SiC single crystal (again not shown), wherein an SiC seed crystal 2 examined using measuring technology according to FIG. 1 and thus being classified into the second class is used. As a stress-reducing measure, in the case of the growth apparatus 30, in contrast to the growth apparatus 19 according to FIG. 4, another structure for the attachment of the SiC seed crystal 2 within the growth crucible 20 is provided. In this exemplified embodiment, the SiC seed crystal 2 is firmly fixed to the crucible cover 26 by means of a spacer ring 31. The spacer ring 31 is adhered to the SiC seed crystal 2 on the wafer rear side 5. A further adhesive connection exists between the spacer ring 31 and the crucible cover 26 so that overall a firmly joined seed unit 32 is formed which comprises the SiC seed crystal 2, the spacer ring 31 and the crucible cover 26 as components. The spacer ring 31 is disposed concentric to the crystal longitudinal mid-axis 6 and surrounds a central transverse cavity 33 which axially adjoins the wafer rear side 5 of the SiC seed crystal 2. This transverse cavity 33 is empty. Process gas can collect therein during the SiC growth. However, the transverse cavity 33 has a different level of thermal conductivity to the spacer ring 31, consisting e.g. of a graphite material, and so a similar stress-reducing effect results as in the case of the growth apparatus 19 by reason of the stress-reducing elements 17 and 18. Furthermore, the transverse cavity 33 also has an inherent stress-reducing effect. Overall, the initial seed stresses present in the SiC seed crystal 2 mounted in the seed unit 32 are compensated for at least to a large extent during the SiC sublimation growth of the bulk SiC single crystal and preferably not passed on into the growing bulk SiC single crystal. Once again, the result is a very low-stress bulk SiC single crystal.

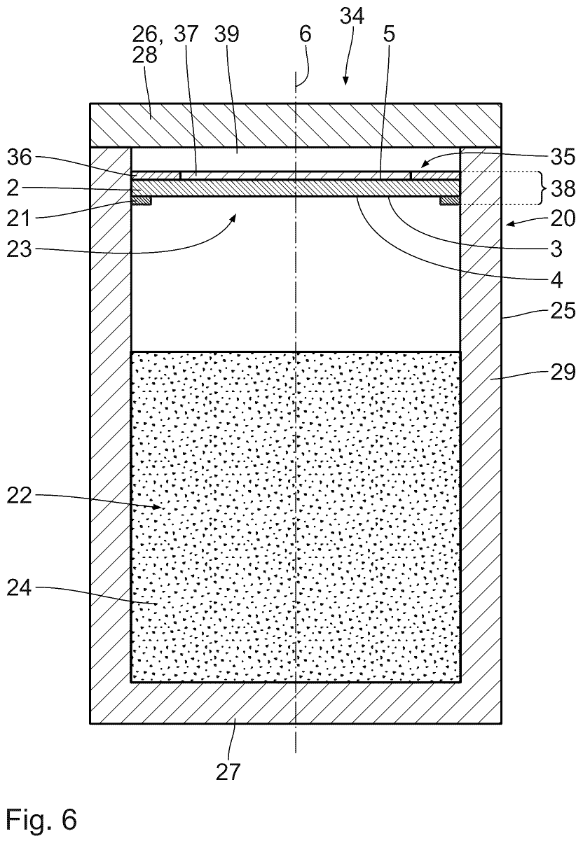

FIG. 6 shows a further exemplified embodiment of a growth apparatus 34 for the growth of a bulk SiC single crystal (again not shown), in which the SiC seed crystal 2 examined by means of the measuring arrangement 1 is directly coated with a rear-side layer component 35 on the wafer rear side 5 in order to counteract the initial seed stresses detected in the crystal micro-structure of the SiC seed crystal 2 as a stress-reducing measure. The rear-side layer component 35 has two layers. It has two layers or individual layers 36 and 37 disposed radially next to each other, which are both disposed concentrically to the crystal longitudinal mid-axis 6. Both individual layers 36 and 37 consist of mutually different layer materials with different levels of heat conductivity and so overall a similar stress-reducing influence results as in the case of growth apparatuses 19 and 30. The SiC seed crystal 2 and the rear-side layer component 35 directly adjoining the wafer rear side 5 form a seed unit 38 which lies loose on the annular seed holder 21 with the wafer front side 4 of the SiC seed crystal 2 in the region of the peripheral edge.

A transverse cavity 39 is disposed on the rear side of the seed unit 38 facing away from the SiC storage area 22. It is located between the crucible cover 26 and the rear-side layer component 35 of the seed unit 38. This transverse cavity 39 constitutes a further stress-reducing measure of the growth apparatus 34. In this respect it is advantageous but only optional. There are alternative exemplified embodiments without such a transverse cavity 39 between the seed unit 38 and the crucible cover 26.

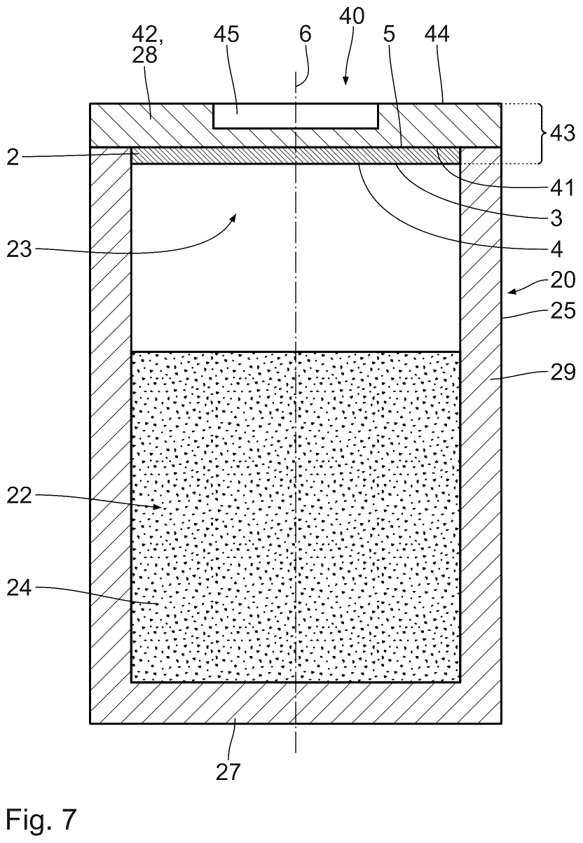

FIG. 7 shows a further exemplified embodiment of a growth apparatus 40 for sublimation growth of a bulk SiC single crystal (again not shown), in which the SiC seed crystal 2, which is classified into the second class according to the determination of the stress distribution using measuring technology, is adhered directly to a cover inner side 41 of the crucible cover 42. This firmly joined unit consisting of the SiC seed crystal 2 and the crucible cover 42 forms a seed unit 43 which comprises a recess 45 as a stress-reducing measure on a cover outer side 44 of the crucible cover 42.

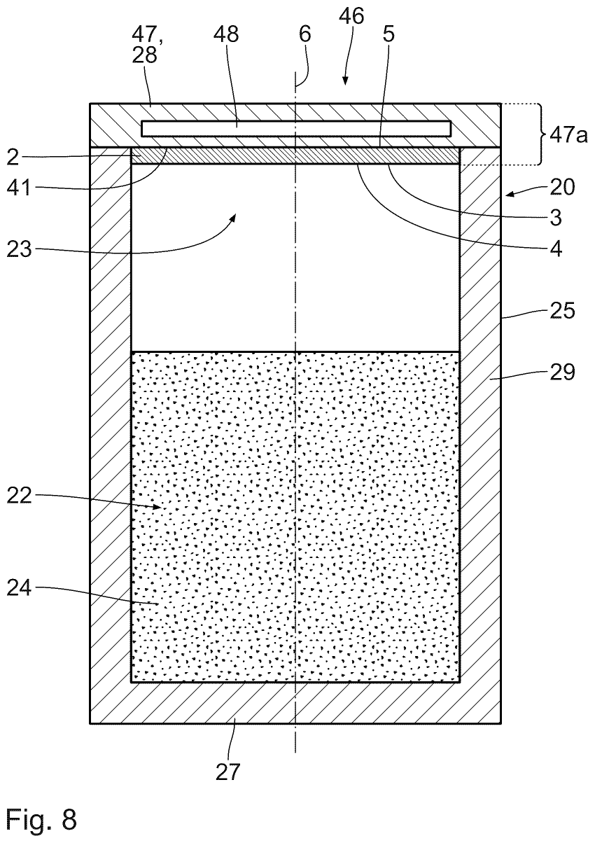

FIG. 8 shows a further exemplified embodiment of a growth apparatus 46 for sublimation growth of a bulk SiC single crystal (again not shown), in which the SiC seed crystal 2, which is classified into the second class according to the determining of the stress distribution using measuring technology, is adhered to the cover inner side 41 of a crucible cover 47. The firmly joined unit consisting of the SiC seed crystal 2 and the crucible cover 47 forms a seed unit 47a. The growth apparatus 46 differs from the growth apparatus 40 according to FIG. 7 substantially by the design of the crucible cover 47. It has, on its inside, an approximately cylindrical and fully embedded transverse cavity 48 which replaces the recess 45 in the growth apparatus 40. Both the internal transverse cavity 48 of the growth apparatus 46 and also the recess 45 of the growth apparatus 40 are stress-reducing measures and in this respect counteract the initial seed stresses detected in the SiC seed crystal 2.

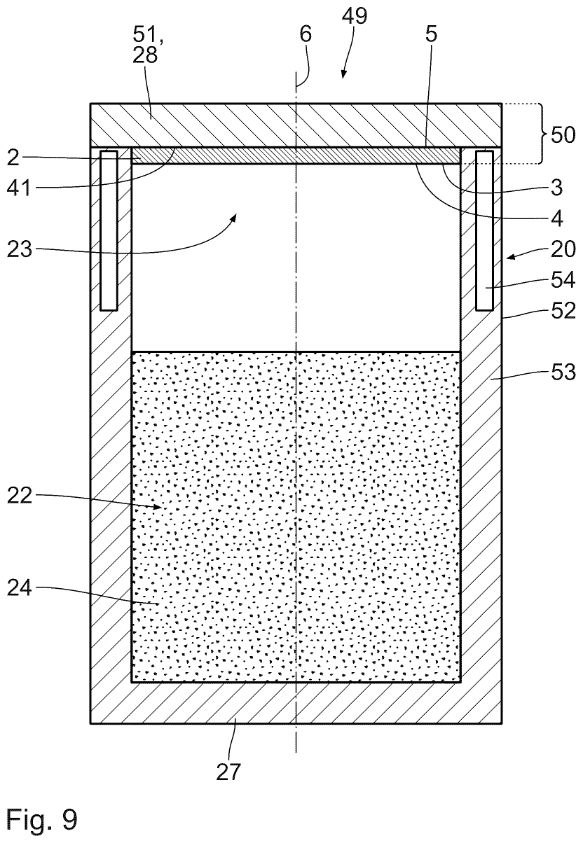

FIG. 9 shows a further exemplified embodiment of a growth apparatus 49 for sublimation growth of a bulk SiC single crystal (again not shown), which comprises a seed unit 50 consisting of a crucible cover 51 and the SiC seed crystal 2 adhered directly on the cover inner side 41. The SiC seed crystal 2 is classified into the second class according to the stress distribution determined using measuring technology and so the growth apparatus 49 has a stress-reducing measure to compensate for the initial seed stresses contained in the SiC seed crystal 2. This is a case of a crucible vessel 52 which comprises, in its side wall 53, an internal completely embedded longitudinal cavity 54. The longitudinal cavity 54 extends in the axial direction and is placed in the axial direction within the side wall 53 in such a way that it tangentially surrounds the SiC seed crystal 2 and the crystal growth area 23.

After termination of the growth process, the bulk SiC single crystal produced by means of the growth apparatuses 19, 30, 34, 40, 46 and 49 can be subjected in particular to a further examination using stress measuring technology. In so doing, the same measuring methods can be used as in the stress measurement on the SiC seed crystal 2, i.e. a measurement of the Raman shift, a measurement of the photoelasticity, an X-ray diffraction measurement and/or a neutron diffraction measurement. Therefore, a complete distribution of the bulk single crystal stresses contained within the grown bulk SiC single crystal can be provided. On the basis thereof, a decision can then be made as to further use. Particularly low-stress and otherwise high-quality bulk SiC single crystals can preferably be used for the production of new SiC seed crystals. Alternatively, however, the bulk SiC single crystals can naturally also be used for the production of SiC substrates for the manufacture of components.

Overall, the above-described sublimation growth processes or growth apparatuses 19, 30, 34, 40, 46 and 49 using suitable stress-reducing measures make possible the production of very low-stress bulk SiC single crystals.

1. A method for producing bulk silicon carbide (SiC) single crystal by sublimation growth, the method comprising:
a) carrying out a stress measurement to detect initial internal mechanical seed stresses on a wafer-shaped single crystalline SiC seed crystal, the SiC seed crystal having a wafer front side with a growth surface intended for a growth of the bulk SiC single crystal to be grown, a wafer rear side and a crystal longitudinal mid-axis extending in an axial direction, and wherein a radial direction is orientated perpendicularly to the axial direction;
b) carrying out a classification of the SiC seed crystal with the aid of the stress measurement, to thereby classify the SiC seed crystal:
b1) into a first class when the detected initial seed stresses are below a first stress boundary value;
b2) into a second class when the detected initial seed stresses lie between the first stress boundary value and a second stress boundary value; or
b3) into a third class when the detected initial seed stresses exceed the second stress boundary value;
and
c) carrying out the sublimation growth, during which the bulk SiC single crystal grows on the SiC seed crystal, with the SiC seed crystal only when the SiC seed crystal has been classified into the first class or into the second class;
c1) when the SiC seed crystal has been classified into the second class, carrying out at least one stress-reducing measure.

2. The method according to claim 1, which comprises, with the aid of the stress measurement, determining a stress distribution of the initial seed stresses in the SiC seed crystal.

3. The method according to claim 1, wherein a stress difference which is measured between a center of the SiC seed crystal disposed on the crystal longitudinal mid-axis and a radial edge region of the SiC seed crystal and which lies in a range between 5 MPa and 15 MPa, is used as a first stress boundary value.

4. The method according to claim 3, which comprises using as the first stress boundary value a stress difference that lies in a range between 7.5 MPa and 12.5 MPa.

5. The method according to claim 3, which comprises using as the first stress boundary value a stress difference of 10 MPa.

6. The method according to claim 1, wherein a stress difference which is measured between a center of the SiC seed crystal disposed on the crystal longitudinal mid-axis and a radial edge region of the SiC seed crystal and which lies in a range between 400 MPa and 600 MPa is used as a second stress boundary value.

7. The method according to claim 6, which comprises using a stress difference that lies in a range between 450 MPa and 550 MPa as the second stress boundary value.

8. The method according to claim 6, which comprises using a stress difference of 500 MPa as the second stress boundary value.

9. The method according to claim 1, which comprises carrying out the stress measurement on the SiC seed crystal by an X-ray diffraction measurement, a neutron diffraction measurement, a measurement of a Raman shift, or a measurement of a photoelasticity.

10. The method according to claim 1, wherein the at least one stress-reducing measure comprises bringing the wafer rear side of the SiC seed crystal into contact with stress-reducing elements having different levels of heat conductivity.

11. The method according to claim 1, wherein the at least one stress-reducing measure comprises using an apparatus for the sublimation growth which is formed with at least one transverse cavity in a region axially adjoining the wafer rear side of the SiC seed crystal when the SiC seed crystal is introduced into the apparatus.

12. The method according to claim 11, wherein the transverse cavity is disposed directly adjacent the wafer rear side of the SiC seed crystal.

13. The method according to claim 11, wherein the transverse cavity is formed in an axial front end wall of a growth crucible used for the sublimation growth as a component of the apparatus.

14. The method according to claim 1, wherein the at least one stress-reducing measure comprises using an apparatus with a growth crucible for the sublimation growth, wherein an axial front end wall of the growth crucible adjacent the SiC seed crystal introduced into the apparatus is formed with at least one recess.

15. The method according to claim 1, wherein the at least one stress-reducing measure comprises using an apparatus with a growth crucible for the sublimation growth, wherein a side wall of the growth crucible surrounding the SiC seed crystal and a crystal growth area is formed with at least one longitudinal cavity.

16. The method according to claim 1, wherein the at least one stress-reducing measure comprises coating the wafer rear side of the SiC seed crystal with a rear-side layer component.

17. The method according to claim 16, which comprises forming the rear-side layer component from at least two mutually different layer materials with mutually different levels of heat conductivity.

18. The method according to claim 1, which comprises determining a stress distribution of the internal mechanical bulk single crystal stresses in the produced bulk SiC single crystal and, based on the stress distribution so determined, determining a further use of the bulk SiC single crystal.

19. The method according to claim 18, which comprises determining the stress distribution of the bulk single crystal stresses by one of an X-ray diffraction measurement, a neutron diffraction measurement, a measurement of the Raman shift, or a measurement of the photoelasticity.
